(19) United States
(12) Patent Application Publication
(10) Pub. No.: US 2004/0253777 A1
(43) Pub. Date: Dec. 16, 2004

(54) Method and apparatus for forming film

(76) Inventors: Hidenori Miyoshi, Tsukuba-shi (JP); Masahito Sugiura, Nirasaki-shi (JP); Yusaku Kashiwagi, Nirasaki-shi (JP); Yoshihisa Kagawa, Nirasaki-shi (JP); Tomohiro Ohta, Nirasaki-shi (JP)

Correspondence Address: Crowell & Moring, PO Box 14300, Washington, DC, 20044-4300, US

(21) Appl. No.: 10/487,989

(22) PCT Filed: Aug. 30, 2002
(86) PCT No.: PCT/JP02/08819

(30) Foreign Application Priority Data
Aug. 30, 2001 (JP) 2001261443

(51) Int. Cl. H01L 21/8238

(52) U.S. Cl. 438/200

(57) ABSTRACT

A process gas constituted by a compound having a ring structure in its molecules is introduced into a chamber (12). In the meantime, an excitation gas such as argon, etc. is excited by an activator (34) and introduced into the chamber (12), so that the process gas is excited. The excited process gas is deposited on a process target substrate (19), forming a porous low dielectric constant film having ring structures in the film.

### TECHNICAL FIELD

The present invention relates to a film forming method and film forming apparatus for forming a film having a predetermined dielectric property.

### BACKGROUND ART

Recently, multilayering of a semiconductor element and fining of wirings have been advanced in the background of demands for speeding and miniaturizing a semiconductor device. In case of a design rule of 0.15 μm or less for example, there is a problem that the speed of signal transmission through wirings in a multilayer structure is delayed and desired speeding can not be achieved. It is effective to use an interlayer insulation film having a low dielectric constant in order to prevent increase in such a wiring delay accompanying the miniaturization.

Conventionally, various materials for forming an insulation film have been examined from this aspect. Particularly, attention has been paid to a porous film having pores of atomic level formed therein to realize a lower dielectric constant than the dielectric constant inherent in the material itself.

As a method of forming a porous low dielectric constant film, there has been developed a method of forming an insulation film by using a material having a ring structure as the starting substance. Since a ring structure essentially includes a pore thereinside, a porous film can be formed by combining multiple material molecules with their ring structure maintained. Such a method is disclosed in, for example, A. Grill et al, Mat. Res. Soc. Symp. Proc. Vol. 565 (107), 1999.

According to the above-described method, a material having a ring structure is directly excited by a hot filament or as parallel plate plasma, thereby a reaction for forming the film is progressed.

In a case where, for example, ring-like siloxane molecules are used as material, the molecules are combined together by, for example, dissociating a carbon-hydrogen bond of a methyl group by activating the side chains of silicon atoms constituting the ring portions. Since a carbon-hydrogen bond of a methyl group requires lower dissociation energy than a silicon-carbon or silicon-oxygen bond, a carbon-hydrogen bond is dissociated prior to the decomposition of the ring structure. Accordingly, film formation is available with the ring structure maintained.

However, in a case where the material is directly excited as parallel plate plasma as described above, the excitation energy to be given on the material is relatively large. Because of this, not only the desired activation site, but also the necessary ring structure is likely to be destroyed, thereby reducing ring structures in the film being formed. The fewer the ring structures are, the lower the porosity of the film is, making it impossible to achieve a desired low dielectric constant.

As described above, the conventional method of forming a film by directly exciting a starting material having a ring structure has a problem that the ring structure is easily ruined at the time of excitation and a desired low dielectric constant is therefore difficult to obtain.

### DISCLOSURE OF INVENTION

In consideration of the above-described circumstance, an object of the present invention is to provide a film forming method and film forming apparatus which are capable of forming an insulation film having a low dielectric constant.

To achieve the above object, a film forming method according to a first aspect of the resent invention comprises:

a step of placing a process target substrate in a chamber;

a process gas introducing step of introducing a process gas including a substance having a ring structure into the chamber; and

an excitation gas introducing step of introducing an excitation gas for exciting the process gas and being in an excited state, into the chamber.

In the excitation gas introducing step, plasma of the excitation gas may be introduced.

The film forming method may further comprise a step of applying a bias voltage to the process target substrate.

To achieve the above object, a film forming apparatus according to a second aspect of the present invention comprises:

a chamber in which a process target substrate is placed;

a process gas introduction unit for introducing a process gas including a substance having a ring structure into the chamber; and

an excitation gas introduction unit for introducing an excitation gas for exciting the process gas and being in an excited state, into the chamber.

The film forming apparatus may further comprise a plasma generation unit which is provided outside the chamber, and generates plasma of the excitation gas.

The film forming apparatus may further comprise a voltage application unit for applying a bias voltage to the process target substrate.

The process gas may be constituted by a substance including at least any one of a siloxane ring structure, a silazane ring structure, or an organic ring structure as the ring structure.

The excitation gas may be constituted by including at least any one of argon, neon, xenon, hydrogen, nitrogen, oxygen, and methane.

### BRIEF DESCRIPTION OF DRAWINGS

FIG. 1 is a diagram showing a structure of a film forming apparatus according to an embodiment of the present invention.

### BEST MODE FOR CARRYING OUT THE INVENTION

A film forming method and a fabrication apparatus according to an embodiment of the present invention will be explained with reference to the drawings.

According to the present embodiment, explanation will be given of an example where a porous silicon insulation film is formed on a process target substrate such as a semiconductor substrate or the like with the use of a starting substance consisting of a silicon compound having a ring structure.

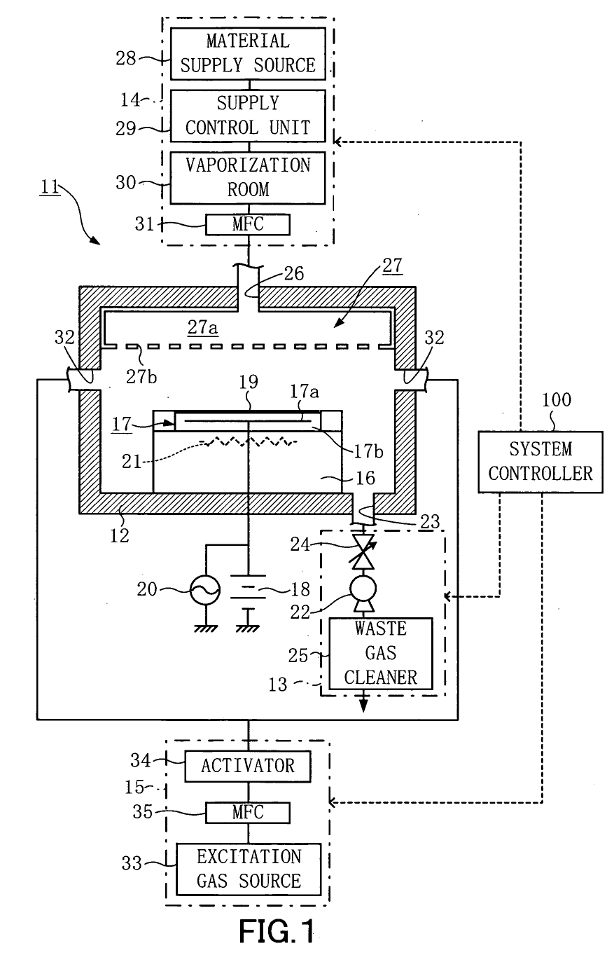

FIG. 1 shows a structure of a film forming apparatus 11 according to the present embodiment.

As shown in FIG. 1, the film forming apparatus 11 of the present embodiment comprises a chamber 12, an evacuation unit 13, a process gas supply unit 14, an excitation gas supply unit 15, and a system controller 100.

The chamber 12 is formed into an approximately cylindrical shape, and is formed of, for example, aluminum whose inner surface has been subjected to an anodizing.

An approximately cylindrical stage 16 is provided in approximately the center of the chamber 12 so as to stand up from the bottom of the chamber 12.

An electrostatic chuck 17 is arranged on the top of the stage 16. The electrostatic chuck 17 is constituted, for example, in such a way that an electrode plate 17a made of tungsten or the like is covered with a dielectric 17b made of aluminum oxide or the like.

The electrode plate 17a inside the dielectric 17b is connected to a direct current power source 18, and a direct current voltage of a predetermined voltage is applied to the electrode plate 17a. A process target substrate 19 is placed on the electrostatic chuck 17. Electric charges are generated in the surface of the dielectric 17b in accordance with a voltage applied to the electrode plate 17a, while electric charges having an opposite polarity to the former electric charges are generated in the back surface of the process target substrate 19 on the dielectric 17b. Due to this, an electrostatic force (Coulomb force) is formed between the dielectric 17b and the process target substrate 19, thereby the process target substrate 19 is attracted onto the dielectric 17b to be held thereon.

The electrode plate 17a is further connected to a high frequency power source 20 to be applied a high frequency voltage of a predetermined frequency (for example, 2 MHz). A predetermined bias voltage, for example, a voltage of approximately −300 V to −20 V is applied to the electrode plate 17a. The bias voltage is applied thereto in order for process activation species to be efficiently attracted to the process target substrate 19.

A heater 21 formed of a resistor or the like is embedded in the stage 16. With supply of electricity from a nonillustrated power source for heater, the heater 21 heats the process target substrate 19 upon the stage 16 to a predetermined temperature.

The heating temperature is set to a temperature necessary for constraining a thermal stress caused near the interface between the surface of the process target substrate 19 and a formed film, and for promoting film formation occurring on the substrate surface. For example, the heating temperature is set to within a temperature range of a room temperature to 400° C. The temperature may be appropriately changed in accordance with a material to be used, the thickness of a film, etc.

If the heating temperature is too high, the ring structures in the film might be decomposed, while if the heating temperature is too low, a crack or the like might be produced in the film formed near the surface of the semiconductor substrate due to a thermal stress.

The evacuation unit 13 comprises a vacuum pump 22, and vacuums the interior of the chamber 12 down to a predetermined vacuum pressure. The vacuum pump 22 is connected via a flow rate control valve 24 to an exhaust port 23 provided at the bottom of the chamber 12. The flow rate control valve 24 is constituted by an APC or the like, and controls the pressure inside the chamber 12 by its opening degree. The vacuum pump 22 is constituted by any one of, for example, a rotary pump, an oil diffusion pump, a turbo molecular pump, a molecular drag pump, etc. that is selected in accordance with a desired pressure range, or by combining these.

The vacuum pump 22 is connected to a waste gas cleaner 25, through which exhaust gas is discharged with its toxic substance detoxified.

A process gas supply port 26 is provided in the ceiling of the chamber 12 so as to penetrate the ceiling. The process gas supply port 26 is connected to a later-described process gas supply unit 14. A process gas is supplied into the chamber 12 via the process gas supply port 26.

The process gas supply port 26 is connected to a shower head 27 provided on the ceiling of the chamber 12. The shower head 27 comprises a hollow portion 27a and multiple gas holes 27b.

The hollow portion 27a is provided inside the shower head 27, and supplied with a process gas from the process gas supply port 26. The gas holes 27b communicate with the hollow portion 27a, and are set so as to be oriented toward the stage 16. A process gas supplied from the process gas supply port 26 is diffused in the hollow portion 27a, and discharged from the multiple gas holes 27b toward the process target substrate 19.

The process gas supply unit 14 comprises a material supply source 28, a supply control unit 29, and a vaporization chamber 30.

The material supply source 28 supplies a starting material consisting of a silicon compound having a ring structure. For example, a siloxane compound, a silazane compound, a silane compound composed by combining an organocyclo group with a silane, etc. can be raised as employable silicon compound.

A siloxane compound having a ring structure is a compound wherein a silicon forming a siloxane framework has a methyl group and a vinyl group as side chains. For example, hexaethylcyclotrisiloxane, hexamethylcyclotrisiloxane, octafenylcyclotetrasiloxane, tetraethylcyclotetrasiloxane, octamethylcyclotetrasiloxane, 1,3,5-trimethyl-1,3,5-trivinylcyclotrisiloxane, 1,3,5,7-tetramethylcyclotetrasiloxane, and 1,3,5,7-tetravinyl-1,3,5,7-tetramethylcyclotetrasiloxane can be raised as a siloxane compound having a ring structure.

A silazane compound having a ring structure is a compound wherein a silicon forming a silazane framework has a methyl group and a vinyl group as side chains. For example, 1,1,3,3,5,5-hexamethylcyclotrisilazane, 1,2,3,4,5,6-hexamethylcyclotrisilazane, octamethylcyclotetrasilazane, 1,3,5,7-tetraethyl-2,4,6, 8-tetramethylcyclotetrasilazane, 1,3,5,7-tetravinyl-2,4,6,8-tetramethylcyclotetrasilazane, 1,2,3-triethyl-2,4,6-trimethylcyclotrisilazane, and 1,2,3-trivinyl-1,3,5-trimethylcyclotrisilazane can be raised as a silazane compound having a ring structure.

A silane compound is a compound having a methyl group, a vinyl group, etc. as side chains, in addition to an organocyclo group. For example, (cyclohexenyloxy) trimethylsilane, cyclopentyltrimethoxysilane, dimethylsila-11-crown-4, dimethylsila-14-crown-5, dimethylsila-17-crown-6, dimethylsila-20-crown-7,1,1-dimethyl-1-sila-2-oxacyclohexan, and phenethyltrimethoxysilane can be raised as silane compound.

As other silicon compounds having a ring structure than those above, for example, 3-fenylheptamethyltrisiloxane, and divinylsiloxanebenzocyclobutene (DVS-BCB) can be raised.

A carbon-hydrogen bond of a methyl group or a carbon-carbon double bond of a vinyl group is lower in dissociation energy than a silicon-oxygen bond, a silicon-nitrogen bond, a silicon-carbon bond forming the ring structure. Therefore, by providing a relatively low excitation energy, the methyl group, the vinyl group, etc. can be excited while decomposition of the ring structures is reduced. A porous low dielectric constant film with multiple ring structures maintained is formed through bonding of the materials together via the excited methyl group, vinyl group, etc.

As will be described later, according to the present embodiment, the material (process gas) is indirectly excited by contacting plasma of an excitation gas. Therefore, it is possible to form a porous film having a high ring structure content, by exciting a process gas composed of the above listed material with a relatively low energy.

The porosity of the film to be formed is determined by the molecule structure (particularly, the ring structure) of the material. Due to this, by appropriately selecting the material, an insulation film having a desired low dielectric property can be obtained.

The supply control unit 29 controls supply of the material from the material supply source 28. The aforementioned silicon compounds having a ring structure are normally solid or liquid in an air atmosphere. A fixed amount feeder of a predetermined structure or the like can be used as the supply control unit 29 in case of the material being solid, and a gear pump or the like can be used as the supply control unit 29 in case of the material being liquid. The supply control unit 29 supplies the material of a predetermined amount per unit time to the vaporization chamber 30 to be described later.

The vaporization chamber 30 comprises a heating mechanism such as a heater, a heating lamp, etc., and is constituted by a container whose interior can be heated. The interior of the vaporization chamber 30 is heated to a temperature equal to or greater than a temperature (boiling point or sublimation temperature) at which the solid or liquid material supplied from a material supply unit vaporizes. The vaporization chamber 30 is connected to the process gas supply port 26 via a mass flow controller (MFC) 31. The material (the silicon compound having a ring structure) is vaporized in the vaporization chamber 30, controlled to a predetermined flow rate by the MFC 31, and supplied into the chamber 12.

Excitation gas supply ports 32 are provided to the side wall of the chamber 12. For example, two number of the excitation gas supply ports 32 are provided to the side wall of the chamber 12 so as to be opposed to each other. The number of the excitation gas supply ports 32 to be provided may be three or more. The respective excitation gas supply ports 32 are connected to the excitation gas supply unit 15 to be described later.

The excitation gas supply unit 15 comprises an excitation gas source 33 and an activator 34.

The excitation gas source 33 supplies an excitation gas for exciting (activating) the above-described starting material gas in the chamber 12. The excitation gas may be a substance that can excite the process gas to be used, and may be selected from argon (Ar), neon (Ne), xenon (Xe), hydrogen (H₂), nitrogen (N₂), oxygen (O₂), methane (CH)₄, etc.

The activator 34 is connected to the excitation gas source 33 via an MFC 35. The activator 34 comprises a nonillustrated plasma generation mechanism, and activates an excitation gas passing through the activator 34 to generate plasma. The plasma generation mechanism comprised in the activator 34 generates plasma of, for example, a magnetron type, an ECR type, an ICP type, a TCP type, a helicon wave type, etc.

The emission side of the activator 34 is connected to the excitation gas supply ports 32, so that the generated excitation gas plasma will be supplied into the chamber 12 via the excitation gas supply ports 32. The plasma comprises high energy activation species such as radicals, electrolytic ions, etc.

At the time of film forming process, a process gas and an excitation gas plasma are supplied into the chamber 12. The silicon compound having a ring structure, as the process gas, is excited by the activation species such as radicals, etc. included in the excitation gas plasma, thereby forming a polymer film on the surface of the process target substrate 19, as will be specifically described below.

The system controller 100 is a micro-computer control device which comprises an MPU (Micro Processing Unit), a memory, etc. The system controller 100 stores in the memory a program for controlling the operation of the processing apparatus in accordance with a predetermined process sequence, and sends control signals to the respective units of the processing apparatus such as the evacuation unit 13, the process gas supply unit 14, the excitation gas supply unit 15, etc.

Next, an operation of the film forming apparatus 11 having the above-described structure will be explained. In the example below, there will be explained a case where silicon insulation film is formed by using octamethylcyclotetrasiloxane expressed by a chemical formula 1 as the starting material. Also, a case where Ar is used as the excitation gas will be explained.

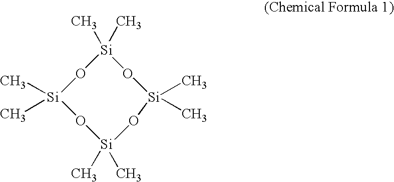

First, the process target substrate 19 is placed on the stage 16 and fixed thereon by the electrostatic chuck 17. After this, the system controller 100 controls the inside of the chamber 12 to a predetermined pressure, for example, approximately 1.3 Pa to 1.3 kPa (10 mTorr to 10 Torr) by the evacuation unit 13.

In the meantime, the system controller 100 heats the process target substrate 19 to a predetermined temperature, for example, approximately 100° C. by the heater 21, and applies a bias voltage to the process target substrate 19.

Next, the system controller 100 starts supply of the process gas and excitation gas into the chamber 12 from the process gas supply unit 14 and the excitation gas supply unit 15. Each gas is supplied into the chamber 12 in a predetermined flow rate. Needless to say, a gas of octamethylcyclotetrasiloxane is supplied from the process gas supply source into the chamber 12.

Next, the system controller 100 turns on the activator 34. Due to this, the excitation gas, i.e. Ar plasma is supplied into the chamber 12. The generated plasma includes high energy activation species such as Ar radicals, Ar ions, etc.

These activation species are mixed with the process gas (octamethylcyclotetrasiloxane) in the chamber 12, cause collision, etc. with the process gas molecules, and thereby activate (excite) the process gas molecules. Radicals, ions, etc. of the process gas are generated in the chamber 12 due to the contact with the excitation gas plasma.

During the process, a predetermined bias voltage, for example, approximately −100V is applied to the process target substrate 19 by the electrode plate 17a, and thereby the generated activation species such as the process gas ions, etc. are attracted to the surface of the process target substrate 19. With the species attracted to the surface of the process target substrate 19 and heated, a film forming reaction to be described below is progressed on the surface of the process target substrate 19.

First, bonds lowest in bond dissociation energy among the octamethylcyclotetrasiloxane molecules are mainly excited by the contact with the activation species such as Ar radicals, etc. That is, carbon-hydrogen bonds of the side chain methyl groups of the molecules are most easily excited (dissociated), and thereby radicals of octamethylcyclotetrasiloxane expressed by, for example, a chemical formula 2 below are generated. Other than these, plus ions obtained by hydrogen plus ions bonding with methyl groups, etc. are generated.

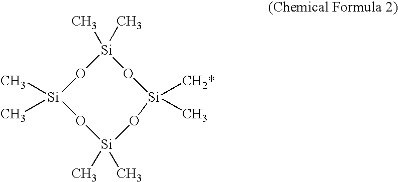

The generated activation species such as octamethylcyclotetrasiloxane radicals, etc. are attracted to the surface of the process target substrate 19 by the bias voltage. The attracted activation species are bonded mainly at the excited side chains, and form polymers expressed by, for example, a chemical formula 3.

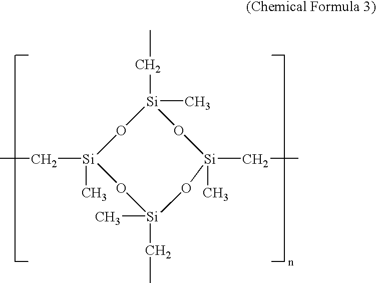

By the bonding of side chains with each other, a film is formed with ring structures maintained in the film as shown by the chemical formula 3. The formed film constitutes a porous low dielectric constant film having a high porosity, because the ring structures have a pore thereinside and form pores therearound in accordance with the level of their steric hindrance.

As described above, a porous film can be formed by exciting a silicon compound having a ring structure. Here, the process gas is “indirectly” excited by the plasma of the excitation gas generated outside the chamber 12.

Accordingly, the excitation energy to be given on the process gas is relatively low, and excitation of other portions than the side chains is restricted. That is, decomposition and destruction of ring structures are restricted and more ring structures can be maintained in the film to be formed, as compared to a case where the plasma of the excitation gas is generated and the process gas is excited in the chamber 12. Therefore, porous insulation film having a lower dielectric constant can be formed.

The film forming reaction is progressed as described above, and a film having a predetermined thickness is formed on the surface of the process target substrate 19. The system controller 100 terminates the film forming process at the time an insulation film having a desired film thickness, for example, approximately 400 nm (4000 Å) is formed. The system controller 100 turns off the activator 34 and then stops the supply of the process gas into the chamber 12. After this, the system controller 100 purges the inside of the chamber 12 for a predetermined time by the excitation gas which is not excited, and stops the application of the bias voltage and heating by the heater 21. Lastly, the process target substrate 19 is transported out of the chamber 12. Thus, the film forming process is completed.

As described above, according to the present embodiment, the process gas comprising a compound having a ring structure is indirectly excited by causing the process gas to contact and be mixed with the excitation gas excited outside the chamber 12. As this example shows, the process gas can be excited with a relatively low excitation energy, by being excited indirectly.

Due to the excitation energy being low, the film forming reaction can be progressed while destruction of the ring structures is restricted. Because of this, a so-called low dielectric constant porous film including many ring structures in the film can be formed.

The present invention is not limited to the explanation of the above-described embodiment, but application, modification, etc. thereof are arbitrary.

In the above-described embodiment, the heater 21 is embedded in the stage 16 so that the process target substrate 19 is heated. However, the heating method is not limited to this, but any kinds of heating method such as a hot wall type, a lamp heating type, etc. are employable.

In the above-described embodiment, the excitation gas is excited as plasma. However, the excitation method of the excitation gas is not limited to this, but an excitation gas excited by, for example, a hot filament, etc. may be introduced into the chamber 12.

In the above-described embodiment, a film (SiC, SiCN, SiOC, etc.) including at least silicon and carbon is formed by using a siloxane compound having a ring structure, a silazane compound having a ring structure, or a silane compound obtained by bonding of organic groups having a ring structure. However, the material to be used and the film kind are not limited to the above-described example.

For example, an SiOF film having ring structures in the film is formed by using the above-described silane compound and a fluorine gas (for example, CF₄, CClF₃, SiF₄, etc.) and activating them with plasma of an oxygen-containing gas. Further, the present invention is applicable to formation of an SiN, SiOCN, SiON or SiOx film.

### Industrial Applicability

The present invention is useful for manufacturing an electronic device such as a semiconductor device, etc.

This application is based on Japanese Patent Application No. 2001-261443 filed on Aug. 30, 2001 and including specification, claims, drawings and summary. The disclosure of the above Japanese Patent Application is incorporated herein by reference in its entirety.

1. A film forming method comprising:
a step of placing a process target substrate (19) in a chamber (11);
a process gas introducing step of introducing a process gas including a substance having a ring structure into said chamber (11); and
an excitation gas introducing step of introducing an excitation gas for exciting the process gas and being in an excited state, into said chamber (11).

2. The film forming method according to claim 1,
wherein in said excitation gas introducing step, plasma of the excitation gas is introduced.

3. The film forming method according to claim 1, further comprising
a step of applying a bias voltage to said process target substrate (19).

4. The film forming method according to claim 2, further comprising
a step of applying a bias voltage to said process target substrate (19).

5. A film forming apparatus comprising:
a chamber (11) in which a process target substrate (19) is placed;
a process gas introduction unit (26) for introducing a process gas including a substance having a ring structure into said chamber (11); and
an excitation gas introduction unit (32) for introducing an excitation gas for exciting the process gas and being in an excited state, into said chamber (11).

6. The film forming apparatus according to claim 5, further comprising
a plasma generation unit (34) which is provided outside said chamber (11), and generates plasma of the excitation gas.

7. The film forming apparatus according to claim 5, further comprising
a voltage application unit (20) for applying a bias voltage to said process target substrate (19).

8. The film forming apparatus according to claim 6, further comprising
a voltage application unit (20) for applying a bias voltage to said process target substrate (19).

9. The film forming apparatus according to claim 5,
wherein the process gas is constituted by a substance including at least any one of a siloxane ring structure, a silazane ring structure, or an organic ring structure as the ring structure.

10. The film forming apparatus according to claim 6,
wherein the process gas is constituted by a substance including at least any one of a siloxane ring structure, a silazane ring structure, or an organic ring structure as the ring structure.

11. The film forming apparatus according to claim 7,
wherein the process gas is constituted by a substance including at least any one of a siloxane ring structure, a silazane ring structure, or an organic ring structure as the ring structure.

12. The film forming apparatus according to claim 8,
wherein the process gas is constituted by a substance including at least any one of a siloxane ring structure, a silazane ring structure, or an organic ring structure as the ring structure.

13. The film forming apparatus according to claim 5,
wherein the excitation gas is constituted by including at least any one of argon, neon, xenon, hydrogen, nitrogen, oxygen, and methane.

14. The film forming apparatus according to claim 6,
wherein the excitation gas is constituted by including at least any one of argon, neon, xenon, hydrogen, nitrogen, oxygen, and methane.

15. The film forming apparatus according to claim 7,
wherein the excitation gas is constituted by including at least any one of argon, neon, xenon, hydrogen, nitrogen, oxygen, and methane.

16. The film forming apparatus according to claim 8,
wherein the excitation gas is constituted by including at least any one of argon, neon, xenon, hydrogen, nitrogen, oxygen, and methane.
